(19) United States
(12) Patent Application Publication
(10) Pub. No.: US 2004/0064634 A1
(43) Pub. Date: Apr. 1, 2004

(54) Method of emulating electrically erasable memory in a motor vehicle microcontroller

(76) Inventors: Mark T. Lowden, Kokomo, IN (US); Paul M. Hay, Noblesville, IN (US); W. James Allen, Carmel, IN (US); Ben F. Mc Cormick II, Fishers, IN (US); Kevin M. Gertiser, Noblesville, IN (US)

Correspondence Address: JIMMY L. FUNKE, DELPHI TECHNOLOGIES, INC., Legal Staff Mail Code: CT10C, P.O. Box 9005, Kokomo, IN, 46904-9005, US

(21) Appl. No.: 10/255,190

(22) Filed: Sep. 26, 2002

(51) Int. Cl. G11C 5/00

(52) U.S. Cl. 711/103; 711/5

(57) ABSTRACT

An improved method of operation for a motor vehicle microcontroller uses flash memory (FM) for storing generic data and emulating an EE memory device. The FM is divided into first and second banks, with the first bank being utilized for generic data and the second bank being utilized for EE data, allowing EE data to be updated while the microcontroller accesses stored generic data. The second bank is partitioned into sectors that are individually erasable, and EE data is updated by storing the updated EE data into an unused sector, flagging the old sector to indicate that it contains invalid data, and later erasing the old sector to make it available for future updates of EE data.

### TECHNICAL FIELD

This invention relates to a method of operation for a motor vehicle microcontroller that stores and retrieves vehicle-specific data from a memory device, and more particularly to a method of using a flash programmable memory device to emulate an electrically erasable memory device.

### BACKGROUND OF THE INVENTION

A motor vehicle microcontroller is frequently required to record vehicle-specific data, including data that is generated in the course of vehicle operation, in a non-volatile memory device. A common way of meeting this requirement is to utilize a small capacity electrically erasable (EE) memory device, such as an EEPROM, for the so-called “electrically erasable data”, along with a larger capacity read-only memory for generic data such as software code and calibration data. More recently, vehicle microcontrollers have utilized a programmable flash memory (FM) for storing the generic data and effectively emulating an EE memory device in the case of vehicle-specific data, thereby eliminating the need for a separate EE memory device. In this case, however, none of the stored data (including the generic data) can be accessed by the microcontroller while portions of the FM are being changed to update the EE data. Since the microcontroller requires unrestricted access to the generic data during vehicle operation, EE data generated during vehicle operation must be temporarily stored in volatile memory such as random access memory (RAM), and then transferred to the FM at engine shut-down. However, this approach is problematic because the data temporarily stored in RAM is liable to be lost due to power interruptions, particularly during the process of transferring the data to the FM. Also, some EE data must be written during vehicle operation, which is precluded using traditional FM devices due to the unrestricted access requirement. Accordingly, what is needed is a method of using FM in a vehicle microcontroller for both storing generic data and emulating an EE memory device, which allows updating of EE data during vehicle operation without interrupting the ability of the microcontroller to access stored generic data.

### SUMMARY OF THE INVENTION

The present invention is directed to an improved method of using FM in a motor vehicle microcontroller for both storing generic data and emulating an EE memory device. According to the invention, the FM is divided into first and second banks, with the first bank being utilized for generic data and the second bank being utilized for EE data that requires updating from time to time, allowing EE data to be updated while the microcontroller accesses stored generic data. The second bank is partitioned into sectors that are individually erasable, and EE data is updated by storing the updated EE data into an unused sector, and then flagging the old sector to indicate that it contains invalid data. Old sectors containing invalid data are then erased at a convenient time, marking them as unused and freeing them for storage of newly updated EE data.

### BRIEF DESCRIPTION OF THE DRAWINGS

FIG. 1 is a block diagram of a vehicle including an engine and an electronic control unit (ECU) comprising a microcontroller and a dual-bank FM according to this invention.

FIG. 2 is a diagram of the ECU of FIG. 1.

FIGS. 3A, 3B and 3C are sector diagrams of the FM of FIG. 1, illustrating a write sequence according to a preferred embodiment of this invention. The diagram of FIG. 3A illustrates an initial condition in which EE table data is stored in a first sector of the FM, the diagram of FIG. 3B illustrates an intermediate condition in which the EE table data stored in the first sector is updated and written to a second sector of the FM, and FIG. 3C illustrates a final condition in which an initial byte of the first sector of the FM is flagged to indicate that such sector no longer contains current EE table data.

### DESCRIPTION OF THE PREFERRED EMBODIMENT

Referring to FIG. 1, the method of this invention is described in the context of an electronic control unit (ECU) 10 for a motor vehicle internal combustion engine 12. The ECU 10 receives various inputs 14 pertaining to engine operation and ambient conditions, and develops outputs for controlling engine operation, including a fuel injection output (FUEL) for engine fuel control (FC) 16, and a spark-timing output (SPARK) for engine spark timing control (SC) 18. The various outputs are developed by a microprocessor or microcontroller (MC) 20 that resides within ECU 10, and result from the execution of various software routines stored within a flash memory device (FM) 24. The software routines and various calibration data used by routines are common to vehicles of a given type and are referred to herein as generic data. In addition to such generic data, FM 24 also stores vehicle-specific data that traditionally has been stored in an electrically erasable memory device such as an EEPROM. Such vehicle-specific data, referred to herein as EE data, may include, for example, the vehicle identification number, security codes for enabling engine starting, and data generated by the software routines in the course of engine operation, such as learned or adaptive calibration data. In the illustrated embodiment, the MC 20 interfaces with FPM 24 via a parallel data link 22, although a serial mechanization is also possible.

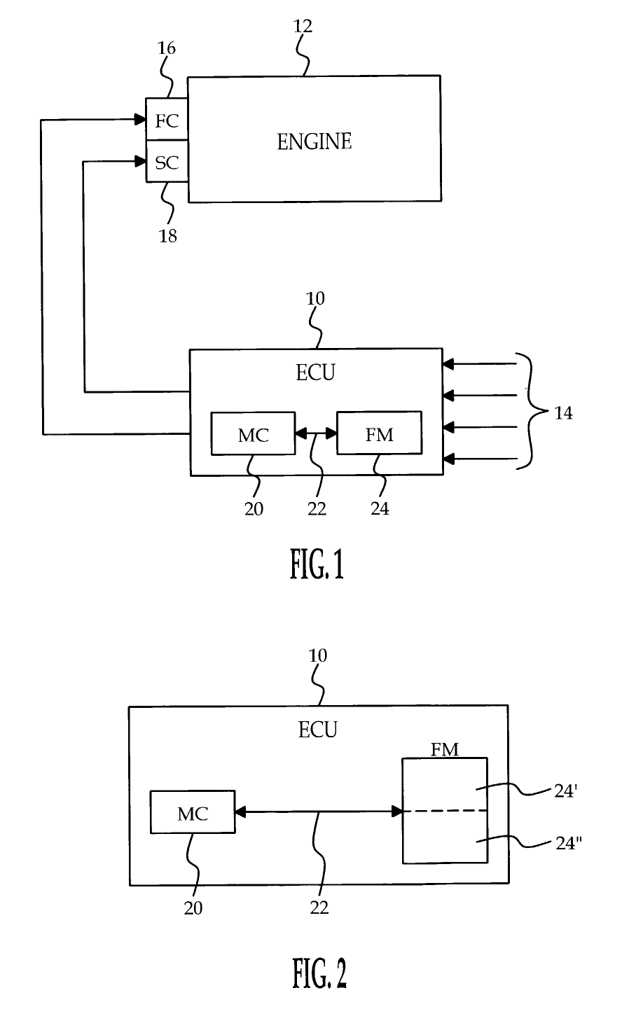

According to the method of the present invention FM 24 is divided into first and second independently accessible banks 24′, 24″, as illustrated in FIG. 2. The first bank 24′ is utilized for generic data and the second bank 24″ is utilized for EE data, so that EE data in the second bank 24″ can be updated while MC 20 accesses stored generic data in the first bank 24′ Thus, EE data may be updated during operation of engine 12, instead of waiting until engine shut-down. This significantly reduces the risk of data loss due to power interruptions associated with battery disconnection when the engine 12 is not running. Although FIG. 1 depicts FM 24 as comprising two banks, an FM having three or more banks is also possible; for example, one or more banks may be utilized for generic data, and the remaining banks may be utilized for EE data.

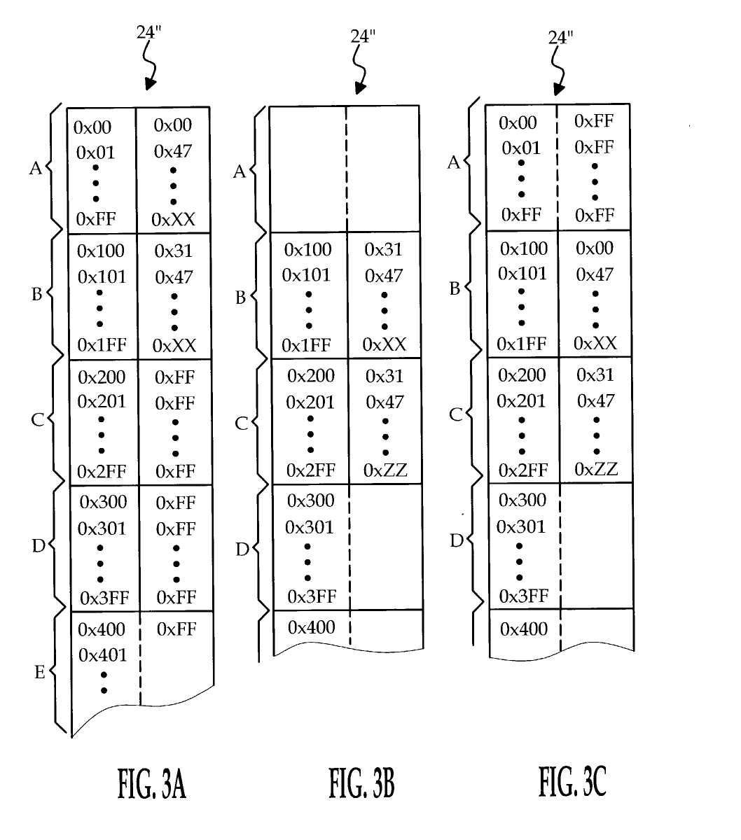

The risk of data loss is further decreased, according to a preferred embodiment of this invention, by utilizing the EE data updating method illustrated by FIGS. 3A-3C, which depict several successive sectors of the second bank 24″ of FM 24. These sectors can be individually erased (set to 0×FF, for example), and the configuration of the sectors, including the number of sectors per bank and the number of bytes per sector, is determined by the flash memory supplier. The sectors are identified by the upper case letters A, B, C, D and so on, and contain 256 bytes of memory. In each of the FIGS. 3A-3C, the numbers in the left-hand column designate the memory address or location, while the numbers in the right-hand column represent the corresponding memory contents in hexadecimal notation. Also, the data stored in the first byte of each sector is coded to indicate whether that sector has been used, and whether it contains current data. Specifically, the first byte of each unused sector is initially set to 0×FF (as seen at bytes 0×200, 0×300 and 0×400 of FIG. 3A) to identify such sectors as being unused, and MC 20 subsequently sets the first byte of a used and invalid sector to 0×00 (as seen at byte 0×100 of FIG. 3A, for example). Thus, in FIG. 3A, sector A is used and invalid, sector B contains current EE data, and sectors C, D and E are unused. The method of updating stored EE data essentially involves three steps. (1) writing the updated data to an unused sector, (2) setting the first byte of the previous sector to 0×00 to identify such sector as used and invalid, and (3) reclaiming used and invalid sectors to unused sectors by erasing them. In the illustration, the data stored in sector B of FIG. 3A is updated to change the last data byte from XX to ZZ. Thus, MC 20 identifies sector C as the next unused sector, and writes the updated data to sector C as illustrated in FIG. 3B. At such point, sector B contains the old EE data, and sector C contains the updated EE data. Once the updated data in sector C is validated, MC 20 sets the first byte of sector B to 00 to identify such sector as used and invalid, as illustrated in FIG. 3C. At a convenient time (e.g., during a power-down sequence), the MC 20 can reclaim sector B and any other used and invalid sectors by erasing them. These sectors are easily identified by the presence of 0×00 in the first byte. The first byte of an erased sector will contain 0×FF, marking such sector as unused and capable of storing a new set of EE data. FIG. 3 illustrates sector A as a reclaimed sector.

While the preceding description illustrates storage of blocks of EE data that are identical in size to the sector size in the second FM bank 24″, this method also allows storage of EE data blocks that are smaller than the sector size. This is accomplished by dividing the sectors into smaller logical blocks, with the same conventions for indicating outdated, current and unused blocks within the sector as described above.

In summary, the method of this invention provides a convenient way of utilizing FM in the context of a motor vehicle microcontroller for storing generic data and emulating an EE memory device, where EE data call be updated during engine operation without interrupting the ability of the microcontroller to access the stored generic data. While this invention has been described in reference to the illustrated embodiment, it is expected that various modifications in addition to those mentioned above will occur to those skilled in the art. Accordingly, it will be understood that methods incorporating such modifications may fall within the scope of this invention, which is defined by the appended claims.

1. A method of operation for a motor vehicle control unit including a microcontroller and a flash memory for storing both generic data that is continuously accessible to the microcontroller during vehicle operation and electrically erasable (EE) data that requires updating from time to time, the method comprising the steps of:
configuring the flash memory into at least first and second banks that are individually accessible by the microcontroller;
storing the generic data in said first bank;
storing the EE data in said second bank; and
operating the microcontroller during operation of the motor vehicle to concurrently update the EE data and access the generic data.

2. The method of operation of claim 1, including the steps of:
configuring said second bank in a series of sectors, including at least first and second sectors; and
storing the EE data in said first sector.

3. The method of operation of claim 2, including the steps of:
storing an updated version of the stored EE data in said second sector;
marking said first sector as containing invalid EE data; and
marking said second sector as containing valid EE data.

4. The method of operation of claim 3, wherein marking said first sector comprises the step of:
storing a predefined data code in a predefined location of such first sector.

5. The method of operation of claim 3, wherein marking said second sector comprises the step of:
storing a predefined data code in a predefined location of such second sector.

6. The method of operation of claim 3, including the step of:
reclaiming said first sector for storage of updated EE data by erasing such first sector and marking such first sector as containing valid EE data.
